(19) United States
(12) Patent Application Publication
(10) Pub. No.: US 2008/0231373 A1
(43) Pub. Date: Sep. 25, 2008

(54) Output Circuit

(76) Inventors: Hafizur Rahman, Gilbert, AZ (US); Prasanth Perugupalli, Chandler, AZ (US); Nagaraj Dixit, Gilbert, AZ (US)

Correspondence Address: COATS & BENNETT/INFINEON TECHNOLOGIES, 1400 CRESCENT GREEN, SUITE 300, CARY, NC, 27518, US

(21) Appl. No.: 11/688,617

(22) Filed: Mar. 20, 2007

(51) Int. Cl. H03F 3/191

(52) U.S. Cl. 330/302

(57) ABSTRACT

One embodiment of the invention provides an output circuit for a transistor. The output circuit includes a first capacitor coupled between ground and a drain electrode of the transistor via a first bond wire and a second bond wire coupling which couples a node between said first bond wire coupling and said first capacitor with ground via a second capacitor.

### BACKGROUND

Radio frequency (RF) power devices are generally known for use as signal amplifiers in wireless communication applications. The operating frequencies for wireless networks have increased as the demand for wireless communication has increased. RF power devices must now have sufficient gain and bandwidth for operation well into the gigahertz range. Gain and bandwidth enhancement of a RF power amplifier package is generally effected by electrically coupling a power transistor to an RF signal source via a suitably designed input matching network and passing the signal to the load through a suitably designed output matching network. In this process of bandwidth enhancement, one important role is played by the bias feed which is usually a λ/4 transmission line from the gate and drain terminals that is terminated on one end with a bank of capacitors to provide a RF short and proper filtering.

FIG. 1 shows such a typical transistor 150 with drain, source and gate electrodes. Also shown is a respective input matching network 135 arranged within the housing of the transistor, a λ/4 transmission line 140 that provides an electrical contact to the transistor, and a bias circuit consisting of a bias voltage source 110, parallel coupled capacitors 115, 120, 125, and a series connected resistor 130 that is coupled to the transmission line 140 of transistor 150.

A typical output matching network includes a DC blocking capacitor 175 coupled to the output via a bond wire whose resistance and inductance are depicted by respective elements 165 and 170. The other bond wire 180 shown in the output matching network has a resistance and inductance that is depicted as an inductor only for ease of illustration. The bond wire 180 couples to the drain electrode with a λ/4 transmission line 190 which forms the externally accessible contact.

Due to its design, such a power transistor device typically has an undesired high gain peak around 100 MHz which is due to drain side matching. FIG. 2 shows an exemplary measured small signal gain response for a typical RF power transistor for a bandwidth that ranges between 10 MHz and 3 GHz. As can be seen around 100 MHz, a low frequency gain peak (10) is prominent. In this particular measurement, the gain peak (10) amounts to 1.868 dB at 99.7 MHz. Such a peak makes the device susceptible to oscillation and consequently may damage the device if there is an unwanted excitation close to that frequency. A second peak (20) in this diagram is within the normal operating frequency range and is about 13 dB at 1.9 GHz. In measurements it has been shown that if the device breaks into oscillation, the oscillation frequency is the same as the frequency of this gain peak and its harmonics. The gain peak may also have a negative impact on the video bandwidth that can be achieved by such a device for next generation applications. A low point (30) in the gain response around 750 MHz is due to DC decoupling with capacitor 175. The shunt bond wire inductance 165 produces a resonance around 750 MHz.

To minimize the low frequency gain peak, the resistor 130 has a resistance of 10Ω. This series resistor 130 is used at the gate bias feed to reduce the level of the low frequency gain peak to help stabilize and bias the device. If no resistor is used in the bias path, it is not possible to bias transistor 150 to the required quiescent current before it breaks into oscillation. However, this resistor does not dampen the gain peek adequately to mitigate the damage that can occur to transistor 150 when an unwanted excitation close to the gain peak frequency appears at the input of the device. Hence, there exists a need for an improved RF power device.

### SUMMARY

One embodiment of the invention provides an output circuit for a transistor. The output circuit includes a first capacitor coupled between ground and a drain electrode of the transistor via a first bond wire; and a second bond wire coupling which couples a node between said first bond wire coupling and said first capacitor with ground via a second capacitor.

### BRIEF DESCRIPTION OF THE DRAWINGS

The present invention is better understood by reading the following description of non-limiting embodiments with reference to the attached drawings which are briefly described as follows.

FIG. 1 shows a conventional circuit.

FIG. 2 shows an exemplary small signal gain response for the circuit shown in FIG. 1.

FIG. 3 shows an embodiment of a power transistor with an output matching network.

FIG. 4 shows an embodiment of a power transistor with a bias input network and an output matching network.

FIG. 5 shows a comparison of measured small signal gain responses for a circuit as shown in FIG. 1, FIG. 3 and FIG. 4.

FIG. 6 shows a frequency sweep for a 100 watt transistor package using an embodiment of a circuit according to FIGS. 3 and 4.

FIG. 7 shows a frequency sweep for a 30 watt transistor package using an embodiment of a circuit according to FIGS. 3 and 4.

FIG. 8 shows a top view of an embodiment of a power transistor package.

FIG. 9 shows an illustration of an embodiment of a test assembly using a power transistor package as shown in FIG. 8.

FIG. 10 shows an embodiment of a power transistor with an output matching network.

It is to be noted, however, that the appended drawings illustrate only a few aspects of certain embodiments of the invention and are therefore not limiting as to their scope, as the invention encompasses equally effective additional or equivalent embodiments.

### DETAILED DESCRIPTION

In one embodiment, a power device may comprise an RF power transistor die comprising a drain electrode, a drain matching network coupled with the drain electrode, the drain matching network comprising a first capacitor which is coupled between the drain electrode and ground via a first bond wire and may comprise a second bond wire which couples a node between the first bond wire and the first capacitor with ground via a second capacitor.

In one embodiment, the drain electrode can be coupled with a λ/4 transmission line via a third bond wire. In one embodiment, the first bond wire may comprise a plurality of parallel connected bond wires. In one embodiment, the third bond wire comprises a plurality of parallel connected bond wires. In one embodiment, the third bond wire may comprise a plurality of sets of bond wires, each set comprising a plurality of parallel connected bond wires. In one embodiment, the second bond wire may comprise a plurality of parallel connected bond wires. In one embodiment, the RF power transistor can be a vertical LDMOS transistor. In one embodiment, the first bond wire may have an inductance of around 200 pH, the first capacitor may have a capacitance of around 750 pF, the second bond wire may have an inductance of around 100 pH and the second capacitor may have a capacitance of 7.5-10 nF. In one embodiment, the first bond wire may have a resistance of around 0.01Ω. In one embodiment, a third capacitor can be coupled in parallel with said second capacitor.

In another embodiment, a power device may comprise a substrate, a first output transmission line, a second input transmission line, and an RF power transistor die comprising a gate electrode and a drain electrode that is arranged between the first and second transmission lines on the substrate. The power device may comprise an input matching network coupled between the second transmission line and the gate electrode, and a drain matching network coupled between the drain electrode and the first transmission line. The drain matching network comprises a first capacitor which is coupled between the drain electrode and ground via a first bond wire and comprises a second bond wire which couples a node between the first bond wire and the first capacitor with ground via a second capacitor.

In one embodiment, the transmission line is a λ/4 transmission line. In one embodiment, the transistor die is a vertical LDMOS die having a source electrode coupled with the substrate. In one embodiment, first and second capacitors can be arranged on the substrate such that one terminal of each capacitor is directly coupled with the substrate. In one embodiment, the first and second bond wire each may comprise a plurality of parallel connected bond wires. In one embodiment, the third bond wire may comprise a plurality of sets of bond wires, wherein each set comprises a plurality of parallel connected bond wires. In one embodiment, the second bond wire may comprise a plurality of parallel connected bond wires. In one embodiment, the RF power transistor can be a vertical LDMOS transistor. In one embodiment, the first bond wire may have a inductance of around 200 pH, the first capacitor may have a capacitance of around 750 pF, the second bond wire may have an inductance of around 100 pH and the second capacitor may have a capacitance of 7.5-10 nF. In one embodiment, the first bond wire may have a resistance of around 0.01Ω. In one embodiment, the first capacitor can be arranged between the transistor die and the first transmission line. In one embodiment, the second capacitor can be arranged next to the transistor die and the first capacitor. In one embodiment, the power device may further comprise a plurality of transistor die and associated input and output matching networks.

In yet another embodiment, a method for manufacturing a power device may comprise providing a substrate, arranging an RF power transistor die comprising a gate electrode and a drain electrode on the substrate, and providing a drain matching network by arranging first and second capacitors on the substrate, coupling the drain electrode with the first capacitor via a second bond wire, and coupling the first capacitor with the second capacitor via a third bond wire.

In one embodiment, the method may further comprise the steps of arranging a first output transmission line at least partly on the substrate, arranging a second input transmission line at least partly on the substrate, arranging an input matching network coupled between the second transmission line and the gate electrode on the substrate, and coupling the first transmission line with the drain electrode via a first bond wire. In one embodiment, the transmission line can be a λ/4 transmission line. In one embodiment, the first capacitor can be arranged between the transistor die and the first transmission line. In one embodiment, the second capacitor is arranged next to the transistor die and the first capacitor.

In yet another embodiment, a power device may comprise a substrate, a first output λ/4 transmission line, a second input λ/4 transmission line, and an RF power transistor die comprising a gate electrode and a drain electrode. The transistor die is arranged between the first and second transmission lines on the substrate. An input matching network is coupled between the second transmission line and the gate electrode, and a drain matching network is coupled between the drain electrode and the first transmission line. A first capacitor is arranged on the substrate and is coupled via a first bond wire with the gate electrode, and a second capacitor is arranged on the substrate and is coupled via a second bond wire with the first capacitor.

In yet another embodiment, a power device may comprise a substrate, a first output λ/4 transmission line, a second input λ/4 transmission line, and first and second RF power transistor die. Each RF power transistor die comprises a gate electrode and a drain electrode. The transistor die are arranged next to each other between the first and second transmission lines on the substrate. First and second input matching networks are coupled between the second transmission line and the gate electrode; and first and second drain matching networks are coupled between the drain electrode and the first transmission line. Each drain matching network comprises a first capacitor arranged on the substrate that is coupled via a respective first bond wire with the gate electrode, and a second capacitor arranged on the substrate that is coupled via a respective second bond wire with the first capacitor.

In yet another embodiment, a method may provide an output matching network to match the output impedance of a power transistor package by providing a substrate comprising an RF power transistor die comprising a gate electrode and a drain electrode. The method may provide a drain matching network comprising first and second capacitors on the substrate, wherein the drain electrode of the transistor is coupled with the first capacitor via a second bond wire and the first capacitor is coupled with the second capacitor via a third bond wire.

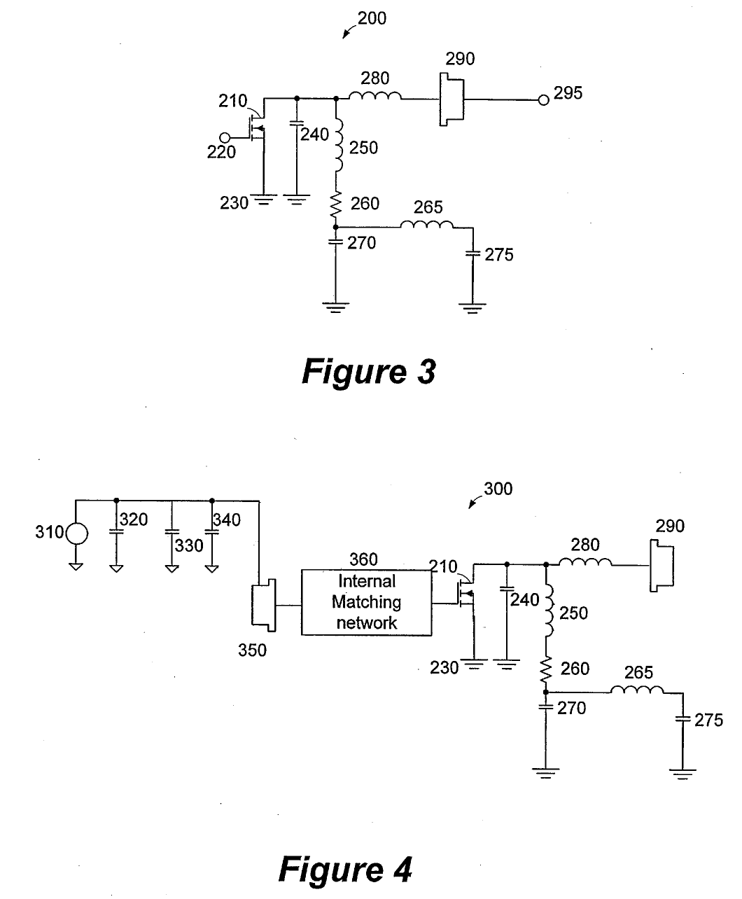

FIG. 3 shows an embodiment of a power transistor with an output matching network. In one embodiment, power transistor 210 comprises a gate electrode 220 and a source electrode 230. In one embodiment, the power transistor is a vertical LDMOS transistor. The self output capacitance of transistor 210 between the drain electrode and ground is denoted with reference numeral 240. In one embodiment, the shunt path includes a bond wire which generally can be described as a series connection of an inductance 250 and a resistance 260 and couples the drain electrode with ground via DC blocking capacitor 270. Again, for a better overview, all other bond wires are shown merely as inductances. In one embodiment, the node between the bond wire 250/260 and the capacitor 270 is coupled with another bond wire 265 that connects to another capacitor 275 in parallel with DC block capacitor 270. A bond wire 280 couples the drain electrode with a λ/4 transmission line 290 which is coupled with an external terminal 295 (not shown).

In one embodiment, the additional bond wire 265 has an inductance of 100 pH and capacitor 275 has a capacitance of 10 nF. In one embodiment, the capacitor 270 has a capacitance of 750 pF and bond wire 250/260 has an inductance of 211 pH and a resistance of 0.01Ω. In one embodiment, capacitor 240 has a capacitance of 30 pF.

FIG. 4 shows an embodiment of a power transistor with a bias input network and an output matching network. In one embodiment, this is the same transistor as shown in FIG. 3 with a modified bias network. In the embodiment illustrated in FIG. 4, the bias circuit comprises a bias voltage source 310 and parallel coupled capacitors 320, 330, 340. More or less capacitors can be used in other embodiments. However, due to the improved drain matching network, no series resistor is used. Thus, in this embodiment, the bias voltage source is directly coupled with the transmission line 350 of transistor 210.

In some embodiments, it has been shown that other changes in the matching network or the bias network cannot reduce the gain peak. Some changes might even create a second low frequency peak. However, the additional LC element with bond wire 265 and capacitance 275 reduces the 100 MHz gain peak so much that a series resistor is not required and the resistor can be removed from the bias feed.

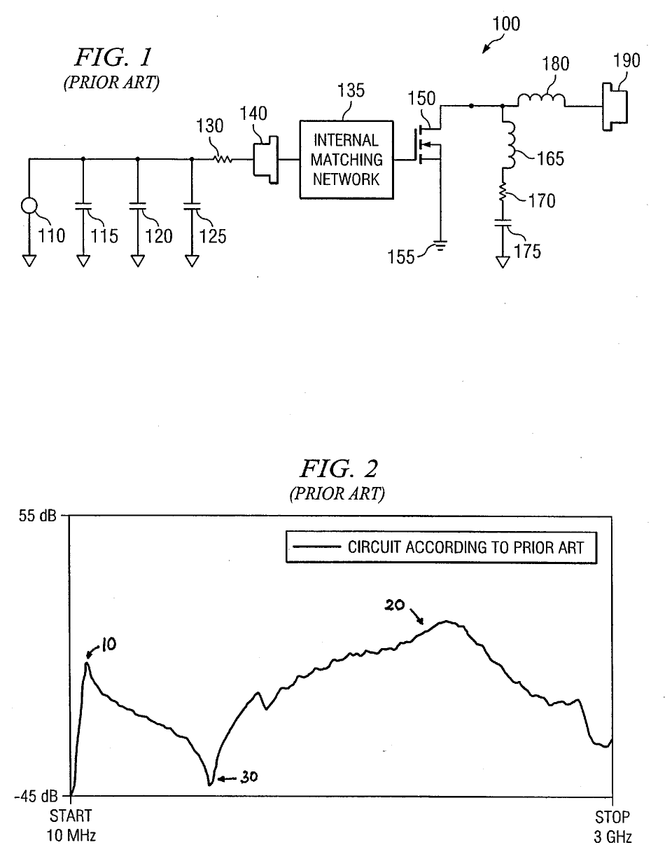

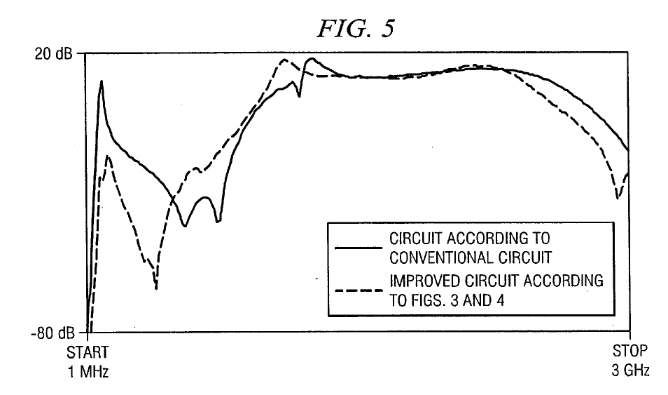

FIG. 5 shows a comparison of measured small signal gain responses for a circuit as shown in FIG. 1, FIG. 3 and FIG. 4. As can be seen, the improvement in the region around 100 MHz is around 30-40 dB and, thus, significantly enhances stability of the power transistor while keeping the usable bandwidth as broad as possible. Due to the additional components the resonance at 750 MHz as seen in FIG. 2 is shifted closer to the low frequency gain peak. The resonance frequency is shifted down to a point around 350 MHz.

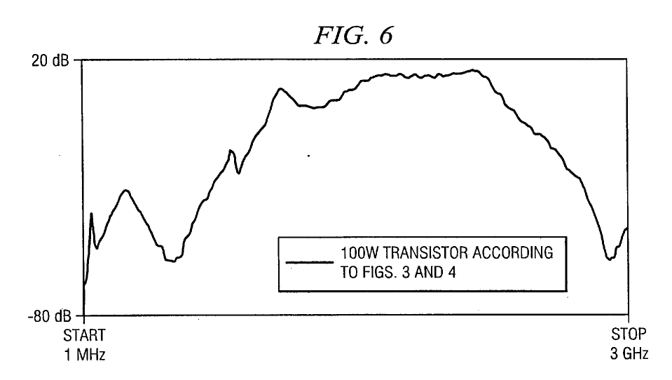

FIG. 6 shows a frequency sweep of a 100 W transistor package using embodiments of the circuit illustrated in FIGS. 3 and 4. The embodiment illustrated in FIG. 6 includes a capacitor 275 that has an exemplary capacitance of 7.5 nF. Again, the in-band gain is not appreciably affected wherein the low frequency gain peak is significantly reduced, thereby reducing the risk of oscillation in that frequency region. In this embodiment around 40 dB suppression of the 90/100 MHz gain peak can be achieved by the bond wire 265 and capacitor 275 as shown in FIGS. 3 and 4 and arranged at the drain of a power transistor. Thus, the device will become extremely rugged and stable in operation.

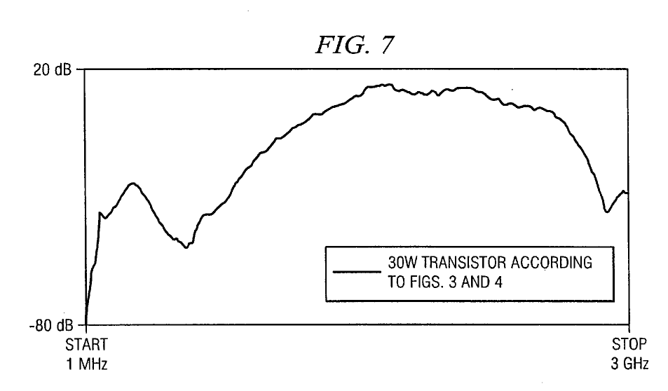

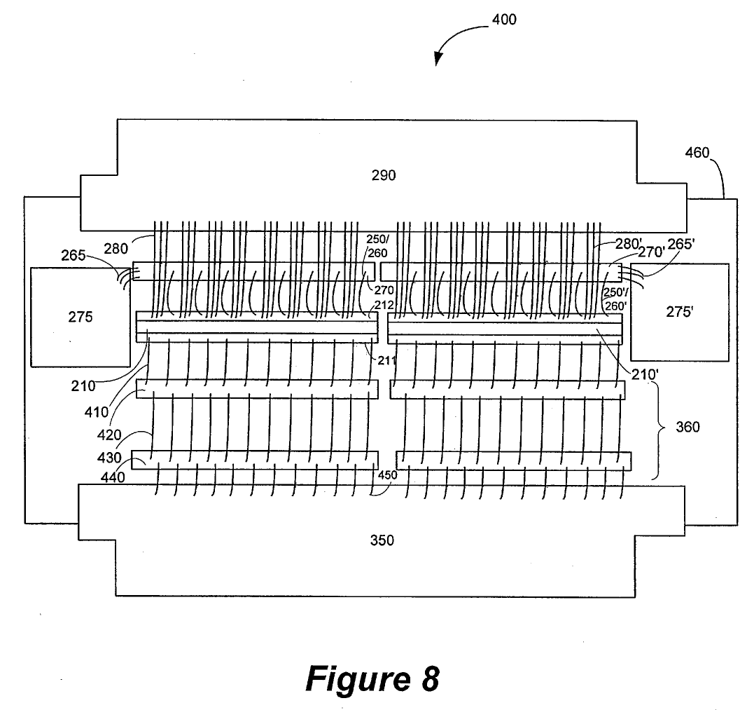

FIG. 7 shows a frequency sweep for a 30 W transistor package using an embodiment of a circuit illustrated in FIGS. 3 and 4.

FIG. 8 shows a top view of an embodiment of an exemplary power transistor housing 460. With respect to FIGS. 3 and 4, similar elements carry similar numerals. On top and bottom, transmission lines 290 and 350 are arranged partially within the housing 460 for externally contacting the transistor. This exemplary embodiment shows a package comprising two transistor die 210, 210′ mounted on a substrate 460. In one embodiment die 210, 210′ are LDMOS transistors. In one embodiment, each die 210, 210′ comprises a vertical LDMOS power transistor. The respective source contact (not shown) is on the bottom of each die 210, 210′ and is coupled with the backside of the substrate 460 for a connection to ground. The package further comprises two internal input matching networks 360 for each transistor die. In the following description, only the elements of the left transistor 210 will be described. The gate matching network couples the gate area 211 via bond wires 410 with a first terminal (top side) of a first capacitor 420 whose second terminal (backside, not shown) is coupled with the backside of substrate 460 and thus ground. This first terminal of capacitor 420 is coupled via bond wires 430 with a first terminal (top side) of a second capacitor 440 whose second terminal (backside, not shown) is coupled with ground via the substrate 460. The first terminal of the second capacitor 440 is coupled with transmission line 350 via an additional set of bond wires 450.

In the illustrated embodiment, the drain electrode 212 is coupled via a set of bond wires 280 with the transmission line 290. To achieve the necessary inductance, one or more bond wire sets are used. In this embodiment, 8 bond wire sets that each have 3 bond wires are used. In other embodiments a different configuration of bond wires or bond wire sets may be used. The first terminal (top side) of capacitor 270 is coupled via bond wires 250/260 with the drain electrode 212. The second terminal (backside, not shown) of capacitor 270 is coupled with the substrate 460 for a connection with ground. The additional capacitors 275, 275′ for each transistor 210, 210′ are arranged on the left and right sides of each die 210, 210′ next to the short sides of capacitor 270 and transistor die 210, respectively, as shown in FIG. 8. The first terminal (top side) of capacitor 275, 275′ is coupled with the first terminal of capacitor 270, 270′ via a set of three bond wires 265, 265′. The second terminal (backside, not shown) is coupled with ground via the substrate.

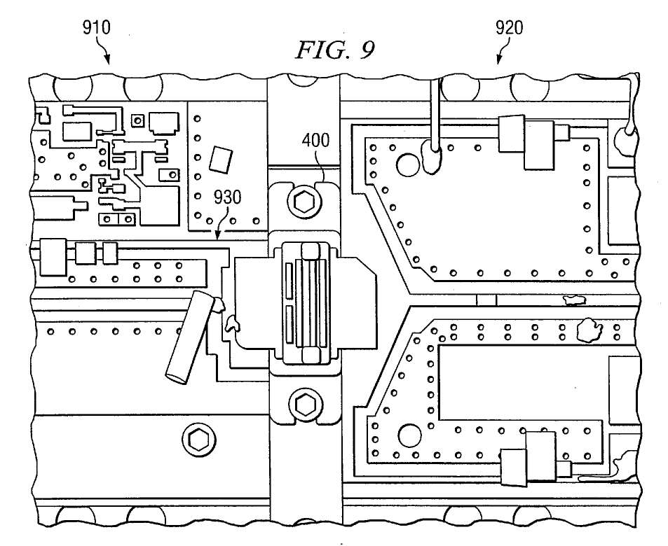

FIG. 9 shows a embodiment of a test assembly using a power transistor package as shown in FIG. 8. In this embodiment, RF power transistor package 460 includes external input matching circuitry 910 and output matching circuitry 920. As can be seen, the location 930 which used to have the serial resistor for the input bias circuit has been replaced by a direct coupling without any resistor. This picture shows a plurality of external components which are used for testing purposes. In other embodiments, other external components can be used.

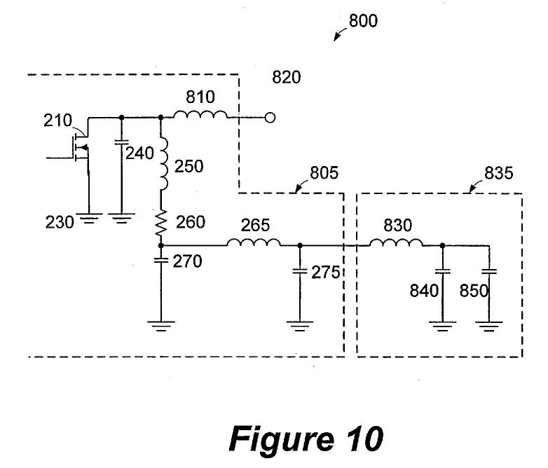

FIG. 10 shows an embodiment of a power transistor with an output matching network. The power transistor illustrated in this embodiment includes inside drain matching circuitry 805 and outside circuitry 835. The dotted lined indicates the inside of a power transistor package and is not closed on the left side to indicate that an input matching network (not shown in FIG. 10) may be provided within the package. In this embodiment, the drain is coupled with an output terminal 820 via a bond wire 810 or a plurality of parallel bond wires. The internal matching network 805, with bond wire 265 and capacitor 275, is extended by an external network 835 that comprises another bond wire 830 that couples the node between bond wire 265 and capacitor 275 via two external capacitors 840 and 850 which are coupled in parallel with ground. A DC bias can be provided at the junction of 830, 840 and 850. Other internal and external networks can be used with the design according to this application as will be appreciated by a person skilled in the art.

Therefore, the present invention is well adapted to carry out the objects and attain the ends and advantages mentioned as well as those that are inherent therein. While numerous changes may be made by those skilled in the art, such changes are encompassed within the spirit of this invention as defined by the appended claims.

What is claimed is:

1. An output circuit for a transistor, comprising:
a first capacitor coupled between ground and a drain electrode of the transistor via a first bond wire; and
a second bond wire coupling which couples a node between said first bond wire coupling and said first capacitor with ground via a second capacitor.

2. The output circuit of claim 1, wherein the output circuit is arranged within a transistor housing.

3. The output circuit of claim 1, wherein said first bond wire coupling comprises a plurality of parallel connected bond wires.

4. The output circuit of claim 1, wherein a ratio of a capacitance value of the second capacitor to the capacitance value of the first capacitor is greater than 30.

5. The output circuit of claim 4, wherein the capacitance value of the second capacitor is equal to or less than 8 nF.

6. The output circuit of claim 1, wherein the drain electrode is coupled with a λ/4 transmission line via a third conductor.

7. The output circuit of claim 1, wherein the transistor comprises an LDMOS transistor.

8. A power device, comprising:
a substrate;
an output transmission line;
an RF power transistor attached to the substrate; and
a drain matching network coupled to a drain electrode of the RF power transistor, wherein the drain matching network comprises a first capacitor coupled to the drain electrode via a first bond wire and a second capacitor coupled to a node between the first bond wire and the first capacitor via a second bond wire, and wherein the drain matching network is coupled to the output transmission line via a third bond wire.

9. The power device of claim 8, wherein the output transmission line comprises a λ/4 transmission line.

10. The power device of claim 8, wherein the RF power transistor comprises a vertical LDMOS transistor.

11. The power device of claim 8, wherein the first and second capacitors are each coupled at one end to the substrate, and wherein the substrate is at a ground potential.

12. The power device of claim 8, wherein the first bond wire comprises a plurality of parallel bond wires.

13. The power device of claim 8, wherein the second bond wire comprises a plurality of parallel bond wires.

14. The power device of claim 8, wherein the third bond wire comprises a plurality of parallel bond wires.

15. The power device of claim 8, wherein a ratio of a capacitance value of the second capacitor to the capacitance value of the first capacitor is greater than 30.

16. The power device of claim 15, wherein the capacitance value of the second capacitor is less than 8 nF.

17. The power device of claim 8, wherein the first bond wire and the second bond wire each have an inductance value that is equal to or less than 300 pH,

18. The power device of claim 17, wherein the inductance value of either the first bond wire or the second bond wire is less than the inductance value of the third bond wire.

19. The power device of claim 8, further comprising:
an input transmission line configured to be directly coupled to a bias voltage source; and
an internal matching network coupled between the input transmission line and a gate of the RF power transistor.

20. A method for manufacturing a power device, comprising:
providing a substrate;
mounting a transistor die, a first capacitor and a second capacitor on the substrate;
coupling a drain electrode of the transistor die with the first capacitor via a first bond wire; and
coupling the second capacitor to a node between the first bond wire and the first capacitor via a second bond wire.

21. A power device, comprising:
a substrate;
an output λ/4 transmission line;
an input λ/4 transmission line;
an RF power transistor die comprising a gate electrode and a drain electrode, the transistor die being arranged between the output and input transmission lines on the substrate;
an input matching network coupled between the input transmission line and the gate electrode; and
a drain matching network coupled between the drain electrode and the output transmission line, wherein the drain matching network comprises a first capacitor arranged on the substrate which is coupled via a first bond wire with the gate electrode and a second capacitor arranged on the substrate which is coupled via a second bond wire with the first capacitor.

22. A method of matching an output impedance of an amplifier, comprising:
providing a substrate;
providing a transistor that comprises a drain node coupled to a first capacitor via a first bond wire; and
lowering a resonant frequency of the amplifier by coupling a resonant circuit on said substrate to a node between the first bond wire and the first capacitor.

23. The method of claim 22, wherein the resonant circuit comprises a second capacitor coupled to the node between the first bond wire and the first capacitor via a second conductor.
